(19) United States
(12) Patent Application Publication
(10) Pub. No.: US 2010/0032760 A1
(43) Pub. Date: Feb. 11, 2010

(54) THIN-FILM TRANSISTOR SUBSTRATE AND METHOD OF FABRICATING THE SAME

(75) Inventors: Seung-Ha CHOI, Siheung-si (KR); Sang-Gab Kim, Seoul (KR); Shin-II Choi, Seoul (KR); Ki-Yeup Lee, Seoul (KR); Dong-Ju Yang, Seoul (KR); Hong-Kee Chin, Suwon-si (KR); Yu-Gwang Jeong, Yongin-si (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/508,972

(22) Filed: Jul. 24, 2009

(30) Foreign Application Priority Data
Aug. 8, 2008 (KR) 10-2008-0078154

(51) Int. Cl. H01L 29/786; H01L 21/20

(52) U.S. Cl. 257/347; 438/479; 257/E29.273; 257/E21.119

(57) ABSTRACT

The present invention provides a thin-film transistor (TFT) substrate, which can be fabricated simply and at reduced cost, and a method of fabricating the TFT substrate. The TFT substrate includes: an insulating substrate; gate wiring that extends on the insulating substrate in a first direction; data wiring that extends on the gate wiring in a second direction, and includes a lower layer and an upper layer; and a semiconductor pattern that is disposed under the data wiring and has substantially the same shape as the data wiring except for a channel region, wherein root-mean-square roughness of a top surface of the data wiring is 3 nm or less.

This application claims priority from and the benefit of Korean Patent Application No. 10-2008-0078154, filed on Aug. 8, 2008, which is hereby incorporated by reference for all purposes as if fully set forth herein.

### BACKGROUND OF THE INVENTION

1. Field of the Invention

The present invention relates to a thin-film transistor (TFT) substrate and a method of fabricating the same, and more particularly, to a TFT substrate, which can be fabricated simply and at reduced cost, and a method of fabricating wiring of the TFT substrate.

2. Discussion of the Background

Liquid crystal displays (LCDs) are one of the most widely used flat panel displays. An LCD may include two substrates having electrodes formed thereon and a liquid crystal layer disposed between the two substrates. The LCD applies voltages to the electrodes to rearrange liquid crystal molecules of the liquid crystal layer, and thus control the amount of light that passes through the liquid crystal layer.

A widely used LCD may include two substrates on which electric-field generating electrodes are formed. Specifically, a plurality of pixel electrodes may be arranged in a matrix on one substrate (a thin-film transistor (TFT) substrate), and a common electrode may cover a whole surface of the other substrate (a common electrode substrate). The LCD displays an image by applying a separate voltage to each pixel electrode. A TFT, which is a three-terminal device for switching a voltage applied to each pixel electrode, may be connected to each pixel electrode. In addition, gate lines and data lines may be formed on the TFT substrate. The gate lines deliver signals to control the TFTs, respectively, and the data lines deliver voltages to the pixel electrodes, respectively.

A conventional LCD may have a triple-layered signal delivery line such as a gate line or a data line. That is, a second conductive layer having barrier characteristics may be formed under a first conductive layer with low resistivity, and a third conductive layer having superior contact characteristics with each pixel electrode may be formed on the first conductive layer. However, as the number of layers that form each signal delivery line increases, the time and cost required to fabricate each signal delivery line also increases.

### SUMMARY OF THE INVENTION

The present invention provides a thin-film transistor (TFT) substrate that can be fabricated simply and at reduced cost.

The present invention also provides a method of fabricating the TFT substrate.

Additional features of the invention will be set forth in the description which follows, and in part will be apparent from the description, or may be learned by practice of the invention.

The present invention discloses a method of fabricating a TFT substrate. The method includes: forming a semiconductor layer and a conductive layer on an insulating substrate, the conductive layer including a lower layer and an upper layer; forming a photosensitive film pattern on the conductive layer, the photosensitive film pattern including a first region and a second region, the second region being formed on both sides of the first region and being thicker than the first region; etching the conductive layer and the semiconductor layer using the photosensitive film pattern as an etching mask; removing the first region of the photosensitive film pattern; etching a portion of the upper layer corresponding to a location of the removed first region; removing the second region of the photosensitive film pattern; and etching a portion of the lower layer corresponding to the location of the removed first region using the upper layer as an etching mask.

The present invention also discloses a TFT substrate including: an insulating substrate; gate wiring that extends on the insulating substrate in a first direction; data wiring that extends on the gate wiring in a second direction and includes a lower layer and an upper layer; and a semiconductor pattern disposed under the data wiring and having substantially the same shape as the data wiring except for a channel region, wherein a root-mean-square roughness of a top surface of the data wiring is 3 nm or less.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view of a thin-film transistor (TFT) substrate according to an exemplary embodiment of the present invention.

FIG. 2 is a cross-sectional view of the TFT substrate taken along line B-B′ of FIG. 1.

FIG. 3, FIG. 4, FIG. 5, FIG. 6, FIG. 7, FIG. 8, FIG. 9, FIG. 10, and FIG. 11 are cross-sectional views of the TFT substrate taken along line C-C′ of FIG. 1 to sequentially explain processes included in a method of fabricating the TFT substrate according to an exemplary embodiment of the present invention.

FIG. 12A shows an atomic force microscope (AFM) image of a top surface of data wiring at a location where Experimental Example 1, Experimental Example 2, and Experimental Example 3 of Table 1 were conducted.

FIG. 12B shows an AFM image of the top surface of the data wiring at a location where Experimental Example 4, Experimental Example 5, and Experimental Example 6 of Table 1 were conducted.

FIG. 13A shows an AFM image of a top surface of data wiring at a location where Comparative Experimental Examples 1, Comparative Experimental Example 2, and Comparative Experimental Example 3 of Table 1 were conducted.

FIG. 13B shows an AFM image of the top surface of the data wiring at a location where Comparative Experimental Example 4, Comparative Experimental Example 5, and Comparative Experimental Example 6 of Table 1 were conducted.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Exemplary embodiments described herein will be described referring to plan views and/or cross-sectional views by way of ideal schematic views of the invention. Accordingly, the exemplary views may be modified depending on manufacturing technologies and/or tolerances. Therefore, the exemplary embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Hereinafter, a thin-film transistor (TFT) substrate according to an exemplary embodiment of the present invention will be described in detail with reference to the attached drawings.

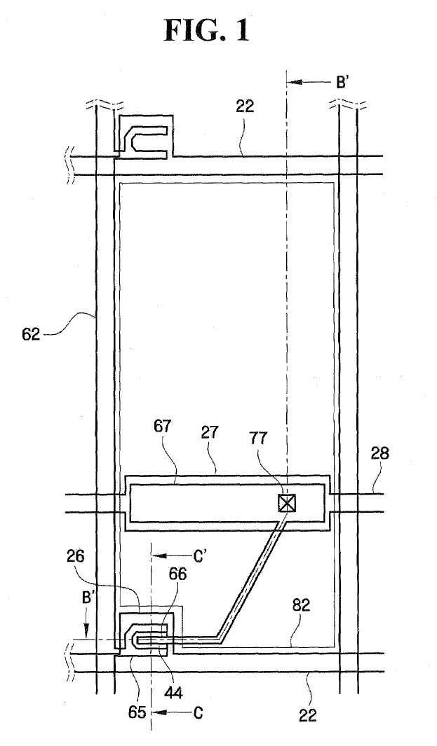

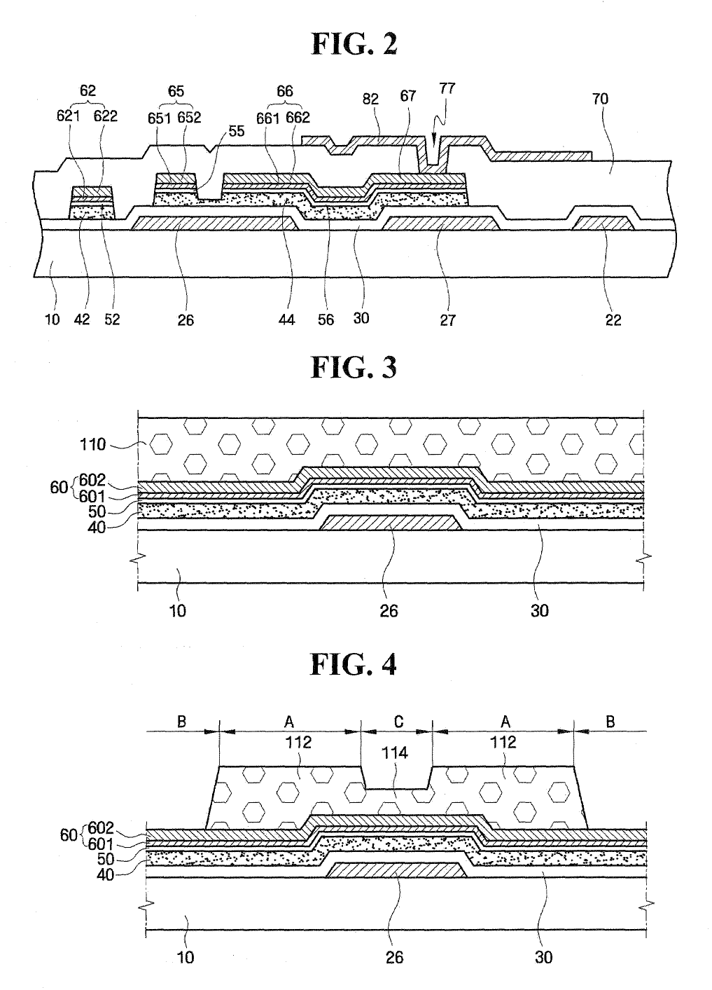

The structure of the TFT substrate according to an exemplary embodiment of the present invention will be described with reference to FIG. 1 and FIG. 2. FIG. 1 is a plan view of the TFT substrate according to an exemplary embodiment of the present invention. FIG. 2 is a cross-sectional view of the TFT substrate taken along line B-B′ of FIG. 1.

Referring to FIG. 1 and FIG. 2, a gate line 22 and a gate electrode 26 are formed on an insulating substrate 10. The gate line 22 extends horizontally, and the gate electrode 26 of a TFT is connected to the gate line 22 and protrudes from the gate line 22. The gate line 22 and the gate electrode 26 are collectively referred to as gate wiring.

A storage electrode line 28 and a storage electrode 27 are also formed on the insulating substrate 10. The storage electrode line 28 extends horizontally across a pixel region and is substantially parallel to the gate line 22. The storage electrode 27 is connected to the storage electrode line 28 and may have a large area. The storage electrode 27 overlaps a drain electrode extension portion 67 that is connected to a pixel electrode 82, which will be described below, to form a storage capacitor that improves the charge storage capability of a pixel. The storage electrode 27 and the storage electrode line 28 are collectively referred to as storage wiring.

The storage wiring may have various shapes and may be disposed at various locations. In addition, if sufficient storage capacitance is generated by the overlapping of the pixel electrode 82 and the gate line 22, the storage wiring may not be formed.

Each of the gate wiring and the storage wiring may be made of aluminum (Al)-based metal such as Al or Al alloy, silver (Ag)-based metal such as Ag or Ag alloy, copper (Cu)-based metal such as Cu or Cu alloy, molybdenum (Mo)-based metal such as Mo or Mo alloy, chrome (Cr), titanium (Ti), or tantalum (Ta).

Each of the gate wiring and the storage wiring may have a multi-layer structure including two conductive layers (not shown) with different physical characteristics. In this case, one of the two conductive layers may be made of a metal with low resistivity, such as an Al-based metal, Ag-based metal, or Cu-based metal, which may reduce a signal delay or a voltage drop of each of the gate wiring and the storage wiring. The other conductive layer may be made of a different material, in particular, a material having superior contact characteristics with indium tin oxide (ITO) and indium zinc oxide (IZO), such as a Mo-based metal, Cr, Ti, or Ta. The multi-layer structure may include, for example, a combination of a lower Cr layer and an upper Al layer and a combination of a lower Al layer and an upper Mo layer.

A gate insulating film 30, which may be made of silicon nitride (SiNx), is formed on the gate wiring and the storage wiring.

Semiconductor patterns 42 and 44, which are made of hydrogenated amorphous silicon or polycrystalline silicon, are formed on the gate insulating film 30. Except in a channel region of the TFT, the semiconductor patterns 42 and 44 are patterned to have substantially the same shape as data wiring, which will be described below. The semiconductor patterns 42 and 44 and the data wiring are patterned by using a single etching mask, which will be described in detail below.

Ohmic contact layers, 52, 55, and 56 are formed on the semiconductor patterns 42 and 44. The ohmic contact layers 52, 55, and 56 are made of silicide or n+ hydrogenated amorphous silicon, which is doped with n-type impurities in high concentration. The ohmic contact layers 52, 55, and 56 are patterned to have substantially the same shape as the data wiring, which will be described below.

A data line 62 and a drain electrode 66 are formed on the ohmic contact layers 52, 55, and 56, and the gate insulating film 30. The data line 62 extends vertically and crosses the gate line 22 to define the pixel. A source electrode 65 protrudes from the data line 62 and extends onto the ohmic contact layer 55. The drain electrode 66 is separated from the source electrode 65 and is formed on the ohmic contact layer 56 to face the source electrode 65 with respect to the gate electrode 26 or the channel region of the TFT. The drain electrode 66 includes the drain electrode extension portion 67, which may have a large area, extends from the drain electrode 66, and overlaps the storage electrode 27. The data line 62, the source electrode 65, the drain electrode 66, and the drain electrode extension portion 67 are collectively referred to as the data wiring.

The data wiring may have a double-layer structure including lower barrier layers 621, 651, and 661, and upper conductive layers 622, 652, and 662. Each of the lower barrier layers 621, 651, and 661 may be made of Mo, Mo alloy, Ti, Ti alloy, Cr, Cr alloy, Ta, or Ta alloy. In addition, each of the upper conductive layers 622, 652, and 662 may be made of Al alloy, which has low resistivity and superior contact characteristics with the pixel electrode 82. The Al alloy is Al added with one or more additional elements selected from nickel (Ni), Cu, boron (B), cerium (Ce), lanthanum (La), and neodymium (Nd). Each of the additional elements may have a concentration of approximately 0.1 to 20 wt %.

The data wiring (i.e., the data line 62, the source electrode 65, the drain electrode 66, and the drain electrode extension portion 67) may be used as an etching mask for patterning the ohmic contact layers 52, 55, and 56 and the semiconductor patterns 42 and 44 under the data wiring in a dry-etching process. Therefore, a top surface of the data wiring may have a low roughness value after the dry-etching process. For example, the root-mean-square roughness of the top surface of the data wiring may be approximately 3 nm or less. The average roughness of the top surface of the data wiring may be approximately 2 nm or less.

The source electrode 65 at least partially overlaps the gate electrode 26, and the drain electrode 66 at least partially overlaps the gate electrode 26 to face the source electrode 65, with the channel region of the TFT disposed therebetween.

The drain electrode extension portion 67 overlaps the storage electrode 27. The drain electrode 66 and the storage electrode 27 form the storage capacitor, with the gate insulating film 30 disposed therebetween. When the storage electrode 27 is not formed, the drain electrode extension portion 67 may not be formed.

The ohmic contact layers 52, 55, and 56 may reduce contact resistance between the semiconductor patterns 42 and 44 thereunder and the data wiring thereabove, and are formed to have substantially the same shape as the data wiring.

Except in the channel region of the TFT, the semiconductor patterns 42 and 44 have substantially the same shape as the data wiring and the ohmic contact layers 52, 55, and 56. That is, the source electrode 65 and the drain electrode 66 are separated from each other by the channel region of the TFT. The ohmic contact layer 55 under the source electrode 65 is also separated from the ohmic contact layer 56 under the drain electrode 66 by the channel region of the TFT. However, the semiconductor pattern 44 is not broken in the channel region and thus defines the channel region of the TFT.

A passivation layer 70 is formed on the data wiring (i.e., the data line 62, the source and drain electrodes 65 and 66, and the drain electrode extension portion 67) and a portion of the semiconductor pattern 44 exposed by the data wiring. The passivation layer 70 may be made of an inorganic material such as silicon nitride or silicon oxide, an organic material having photosensitivity and superior planarization characteristics, or a low-k dielectric material formed by plasma enhanced chemical vapor deposition (PECVD), such as a-Si:C:O or a-Si:O:F. The passivation layer 70 may have a double-layer structure including a lower inorganic layer and an upper organic layer, in order to protect the exposed portion of the semiconductor pattern 44, while taking advantage of the superior characteristics of the organic layer.

A contact hole 77, which exposes the drain electrode extension portion 67, is formed in the passivation layer 70.

The pixel electrode 82, which has a shape that is similar to the shape of the pixel, is disposed on the passivation layer 70. The pixel electrode 82 is electrically connected to the drain electrode extension portion 67 via the contact hole 77. The pixel electrode 82 may be made of a transparent conductor, such as ITO or IZO, or a reflective conductor such as Al.

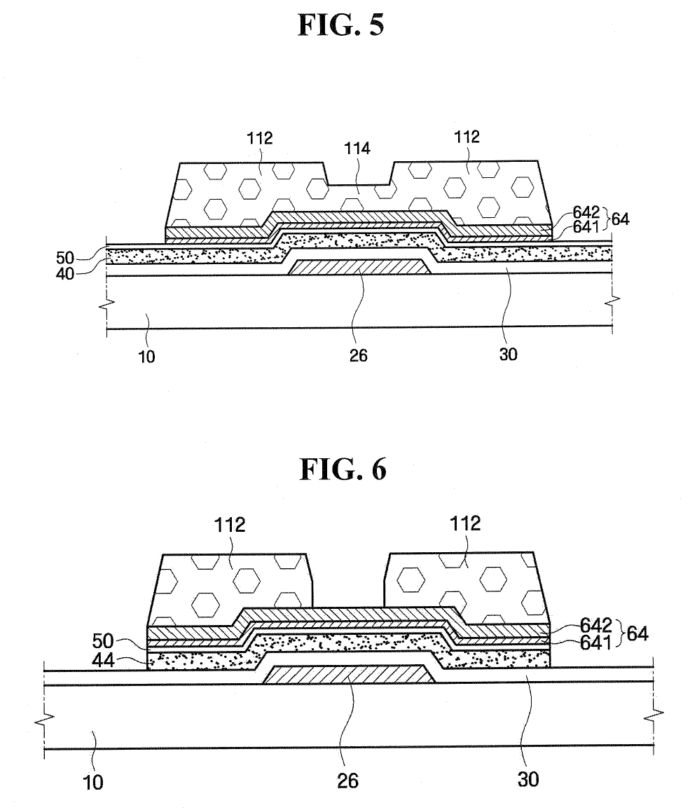

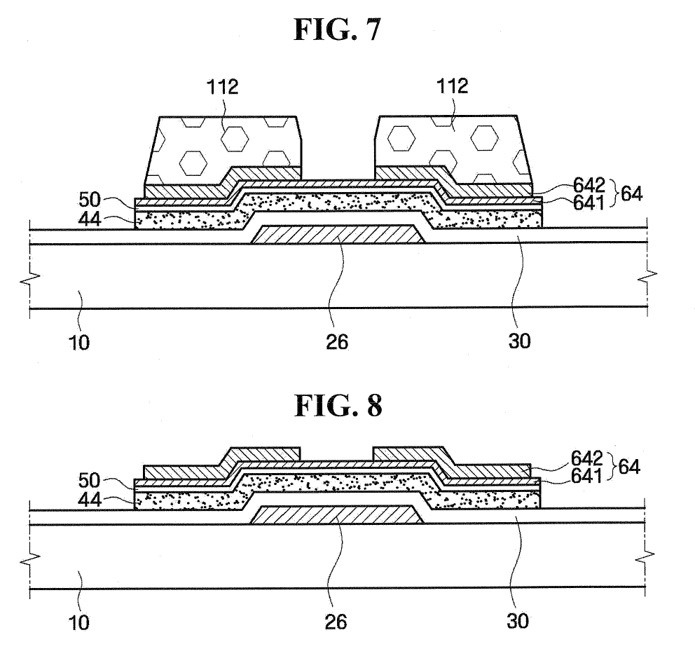

Hereinafter, a method of fabricating the TFT substrate of FIG. 1 according to an exemplary embodiment of the present invention will be described with reference to FIG. 3, FIG. 4, FIG. 5, FIG. 6, FIG. 7, FIG. 8, FIG. 9, FIG. 10, and FIG. 11. FIG. 3, FIG. 4, FIG. 5, FIG. 6, FIG. 7, FIG. 8, FIG. 9, FIG. 10, and FIG. 11 are cross-sectional views of the TFT substrate taken along line C-C′ of FIG. 1 to sequentially explain processes included in the method of fabricating the TFT substrate according to an exemplary embodiment of the present invention.

Referring to FIG. 1 and FIG. 3, a gate metal layer (not shown) is formed on the insulating substrate 10 and then patterned to form the gate line 22, the gate electrode 26, and the storage electrode 27. Each of the gate line 22, the gate electrode 26, and the storage electrode 27 has a double-layer structure including a lower Al or Al alloy layer and an upper Mo or Mo alloy layer. The upper and lower layers of the double-layer structure may be deposited by, for example, sputtering. In addition, the gate line 22, the gate electrode 26, and the storage electrode 27 may be patterned by wet etching or dry etching. For wet etching, phosphoric acid, nitric acid or acetic acid may be used as an etchant. For dry etching, a chorine (Cl)-based etching gas, such as Cl₂ or BCl₃, may be used.

The gate insulating film 30, a semiconductor layer 40, and an ohmic contact layer 50 are sequentially deposited on the insulating substrate 10, the gate wiring (i.e., the gate line 22 and the gate electrode 26), and the storage wiring (i.e., the storage electrode 27 and the storage electrode line 28) by, for example, chemical vapor deposition (CVD).

A data conductive layer 60 is formed on the ohmic contact layer 50 by, for example, sputtering. The data conductive layer 60 may have a double-layer structure including a lower barrier layer 601, which may be made of Mo, Mo alloy, Ti, or Ti alloy, and an upper conductive layer 602, which may be made of an Al alloy. The Al alloy may contain Al and one or more additional elements selected from Ni, Cu, B, Ce, La, and Nd. Next, a photosensitive film 110 is coated on the data conductive layer 60.

Referring to FIG. 1 and FIG. 4, the photosensitive film 110 is exposed to light by using a mask, and then developed to form a photosensitive film pattern. The photosensitive film pattern is divided into two regions having different thicknesses. Specifically, a second region 112, which is thicker than a first region 114, is formed in a data wiring region A, that is, a region where the data wiring is to be formed. The first region 114, which is thinner than the second region 112, is formed in the channel region (indicated by reference character “C” in FIG. 4) of the TFT, that is, a region between the source electrode 65 and the drain electrode 66 (see FIG. 2). Region B of the photosensitive film 110, which excludes the channel region and the data wiring region A, is removed.

The thickness of the photosensitive film 110 according to position, as described above, may be varied using various methods. A slit, a lattice pattern, or a semi-transparent mask may be used to control the amount of light that passes through the photosensitive film 110. The photosensitive film 110 may be made of a material that can reflow. The photosensitive film 110 may be exposed to light by using a conventional mask that is divided into a region through which light can completely pass, and a region through which light cannot completely pass. Then, the photosensitive film 110 may be developed and reflowed, so that part of the photosensitive film 110 can flow to a region without the photosensitive film 110. As a result, the thin first region 114 of the photosensitive film pattern may be formed.

Referring to FIG. 1 and FIG. 5, the data conductive layer 60 is etched by using the photosensitive film pattern (i.e., the first region 114 and the second region 112) as an etching mask to form a conductive layer pattern 64. Here, the data conductive layer 60 may be wet-etched or dry-etched. For wet etching, phosphoric acid, nitric acid, or acetic acid may be used as an etchant. For dry etching, a Cl-based etching gas, such as Cl₂ or BCl₃, may be used. After the data conductive layer 60 is patterned, the conductive layer pattern 64 remains under the photosensitive film pattern. The conductive layer pattern 64 includes a lower barrier layer 641 and an upper conductive layer 642.

Next, exposed portions of the ohmic contact layer 50 and the semiconductor layer 40 under the exposed portions of the ohmic contact layer 50 are dry-etched by using the photosensitive film pattern as an etching mask. While the exposed portions of the ohmic contact layer 50 and the semiconductor layer 40 under the exposed portions of the ohmic contact layer 50 are etched simultaneously, the gate insulating film 30 may not be etched. In this etching process, a Cl-based etching gas or a fluorine (F)-based etching gas may be used. Examples of the Cl-based etching gas may include HCl and Cl₂, and examples of the F-based etching gas include SF₆, XeF₂, BrF₂, and ClF₂.

Referring to FIG. 1 and FIG. 6, a whole surface of the photosensitive film pattern (i.e., the first region 114 and the second region 112) is etched to remove the first region 114, which is thinner than the second region 112, thereby exposing the conductive layer pattern 64 under the first region 114. The thickness of the second region 112 is thereby reduced. The whole surface of the photosensitive film pattern may be etched using an ashing process that uses, for example, oxygen plasma. If the first region 114 is removed when the ohmic contact layer 50 and the semiconductor layer 40 are etched, the ashing process may be omitted. Reference numeral 44 indicates the semiconductor pattern formed by etching the semiconductor layer 40.

In the present exemplary embodiment, after the ohmic contact layer 50 and the semiconductor layer 40 are dry-etched by using the photosensitive film pattern as an etching mask, the whole surface of the photosensitive film pattern is etched. However, the etching processes may be executed in the reverse order. That is, after the whole surface of the photosensitive film pattern is etched, the ohmic contact layer 50 and the semiconductor layer 40 may be etched by using the remaining second region 112 of the photosensitive film pattern as an etching mask.

Referring to FIG. 1 and FIG. 7, a portion of the upper conductive layer 642, which corresponds to the channel region, is dry-etched by using the second region 112 of the photosensitive film pattern as an etching mask. In the present exemplary embodiment, a Cl-based etching gas which has high etch selectivity to the lower barrier layer 641, such as Cl₂ or BCl₃, may be used. When the upper conductive layer 642 is wet-etched, side portions of the upper conductive layer 642, which are already exposed, may also be etched. That is, the data wiring may be over-etched. Therefore, it is difficult to form precise micro-patterns. However, if the upper conductive layer 642 is patterned by dry etching according to the present invention, over-etching of the data wiring can be prevented. Thus, respective side profiles of the semiconductor patterns 42 and 44 may be aligned with that of the data wiring (i.e., the data line 62, the source and drain electrodes 65 and 66, and the drain electrode extension portion 67), which is disposed on the semiconductor patterns 42 and 44.

Plasma treatment may be performed on the upper conductive layer 642 to remove a natural oxide layer formed on the upper conductive layer 642 before the portion of the upper conductive layer 642, which corresponds to the channel region, is etched.

Referring to FIG. 1 and FIG. 8, the second region 112 of the photosensitive film pattern disposed on the conductive layer pattern 64 is removed. The second region 112 of the photosensitive film pattern may be removed by an ashing process that uses, for example, oxygen plasma. While the upper conductive layer 642 is dry-etched, additional elements of an Al alloy that forms the upper conductive layer 642 may react with carbon components of the second region 112 of the photosensitive film pattern and thus remain on the insulating substrate 10 as residues. The residues remain primarily around the data wiring or in the channel region and may cause disconnection or a reduction in electrical conductivity of the data wiring.

Therefore, in the present exemplary embodiment, after the upper conductive layer 642 is dry-etched, the second region 112 of the photosensitive film pattern used as an etching mask in the dry-etching process may be removed in order to prevent the creation of residues. In the present exemplary embodiment, the second region 112 of the photosensitive film pattern may be completely removed. However, the present invention is not limited thereto. A portion of the second region 112 of the photosensitive film pattern can remain on the conductive layer pattern 64 if the second region 112 disposed adjacent to side portions of the conductive layer pattern 64 is removed.

Referring to FIG. 1 and FIG. 9, an exposed portion of the lower barrier layer 641 is dry-etched by using the upper conductive layer 642 as an etching mask. An etching gas used in this dry-etching process may have high etch selectivity to the ohmic contact layer 50. The etching gas may be a mixture of an F-based gas and oxygen. The F-based gas may be SF₆, XeF₂, BrF₂, ClF₂, or a combination of the same. After the exposed portion of the lower barrier layer 641 is dry-etched, the source electrode 65 and the drain electrode 66, which are separated from each other, are formed on the ohmic contact layer 50. The source electrode 65 includes the lower barrier layer 651 and the upper conductive layer 652, and the drain electrode 66 includes the lower barrier layer 661 and the upper conductive layer 662.

In the present exemplary embodiment, the exposed portion of the lower barrier layer 641, which corresponds to the channel region, is etched after the second region 112 of the photosensitive film pattern is removed. Therefore, while the exposed portion of the lower barrier layer 641 is etched, the residues can be completely removed, which, in turn, prevents the residues from reacting with the ohmic contact layer 50 or the semiconductor pattern 44.

Since the upper conductive layer 642 and the second region 112 of the photosensitive film pattern are used as etching masks for the lower barrier layer 641 and the upper conductive layer 642, respectively, the second region 112 of the photosensitive film pattern may be thinner than when it is used as an etching mask for both of the upper conductive layer 642 and the lower barrier layer 641. For example, the thickness of the second region 112 of the photosensitive film pattern may be approximately 1.5 μm or less. Therefore, the time required to perform a photolithography process to pattern the second region 112 of the photosensitive film pattern and perform an ashing process to remove the second region 112 of the photosensitive film pattern can be reduced.

Referring to FIG. 1 and FIG. 10, an exposed portion of the ohmic contact layer 50 is dry-etched by using the upper conductive layer 642 as an etching mask. An etching gas used in this dry-etching process may be an F-based etching gas such as SF₆, XeF₂, BrF₂, ClF₂, or a combination of the same. Here, a portion of the semiconductor pattern 44, which corresponds to the channel region, may be partially removed. Accordingly, the thickness of the portion of the semiconductor pattern 44 may be reduced.

As described above, when the exposed portion of the lower barrier layer 641 and the exposed portion of the ohmic contact layer 50, which correspond to the channel region, are dry-etched by using the upper conductive layer 642 as an etching mask, an F-based etching gas is used instead of a Cl-based etching gas, in order to prevent the corrosion of the upper conductive layer 642, which is made of Al alloy. That is, when a Cl-based etching gas is used, Cl radicals may be attached to and thus corrode the Al alloy of the upper conductive layer 642. However, when an F-based etching gas is used as in the present invention, the corrosion of the Al alloy of the upper conductive layer 642 can be prevented.

When a Cl-based dry-etching gas is used to form the conductive layer pattern 64 as described above with reference to FIG. 5, the upper conductive layers 652 and 662 may be plasma-treated by using an F-based gas in order to prevent the corrosion of the upper conductive layers 652 and 662, which are made of Al alloy. Here, the F-based gas may be CF₄, SF₆, CHF₃, or a combination of the same. The F-based gas may be mixed with O₂, N₂, He, Ar, or H₂, and used accordingly for plasma treatment. For example, a gas mixture of CHF₃ and O₂ may be used. After the upper conductive layers 652 and 662 are plasma-treated by using an F-based gas to form the conductive layer pattern 64, Cl radicals, which are attached to the upper conductive layers 652 and 662, are replaced by F radicals. As a result, the corrosion of the upper conductive layers 652 and 662 can be prevented.

Referring to FIG. 1 and FIG. 11, the passivation layer 70 is formed on the resultant structure of FIG. 10. Then, a photolithography process is performed on the passivation layer 70 to form the contact hole 77, which exposes the drain electrode extension portion 67.

Finally, referring to FIG. 2, a transparent conductor or a reflective conductor is deposited, and a photolithography process is performed on the transparent conductor or the reflective conductor to form the pixel electrode 82, which is connected to the drain electrode 66.

In the present exemplary embodiment, since the portion of the upper conductive layer 642 and that of the lower barrier layer 641, which correspond to the channel region, are patterned by dry etching, portions of the semiconductor pattern 44 which protrude from respective sides of the source electrode 65 and the drain electrode 66, respectively, may be limited to approximately 1 μm or less. When the protruding portions of the semiconductor pattern 44 are exposed to light, leakage current may be generated. However, if the size of the semiconductor pattern 44 is reduced as in the present invention, the generation of leakage current can be controlled.

In the present exemplary embodiment, after the second region 112 of the photosensitive film pattern is removed, the portion of the lower barrier layer 641 and that of the ohmic contact layer 50, which correspond to the channel region, are dry-etched by using the upper conductive layer 642 as an etching mask. Therefore, a top surface of the upper conductive layer 642 may have a low roughness value after the dry-etching process.

Table 1 below shows values obtained by measuring the roughness of respective top surfaces of data wirings, that is, respective top surfaces of upper conductive layers. In Experimental Example 1, Experimental Example 2, Experimental Example 3, Experimental Example 4, Experimental Example 5, and Experimental Example 6, the roughness of the top surface of the data wiring fabricated according to the exemplary embodiment was measured. In Comparative Experimental Example 1, Comparative Experimental Example 2, Comparative Experimental Example 3, Comparative Experimental Example 4, Comparative Experimental Example 5, and Comparative Experimental Example 6, after respective portions of an upper conductive layer, a lower barrier layer, and an ohmic contact layer, which correspond to a channel region, were dry-etched by using a second region of a photosensitive film pattern as an etching mask, the second region of the photosensitive film pattern was removed. Then, the roughness of the top surface of the data wiring was measured.

TABLE 1

| | Average | |
|---|---|---|
| | Roughness | Root-Mean-Square |
| Sample | (nm) | Roughness (nm) |
| Experimental Example 1 | 1.86 | 2.36 |
| Experimental Example 2 | 1.92 | 2.41 |
| Experimental Example 3 | 1.85 | 2.33 |
| Experimental Example 4 | 1.97 | 2.48 |
| Experimental Example 5 | 1.90 | 2.41 |
| Experimental Example 6 | 1.95 | 2.48 |
| Comparative | 2.60 | 3.33 |
| Experimental Example 1 | | |
| Comparative | 2.56 | 3.22 |
| Experimental Example 2 | | |
| Comparative | 2.56 | 3.22 |
| Experimental Example 3 | | |
| Comparative | 2.52 | 3.16 |
| Experimental Example 4 | | |
| Comparative | 2.53 | 3.21 |
| Experimental Example 5 | | |
| Comparative | 2.46 | 3.13 |
| Experimental Example 6 | | |

Referring to Table 1, the average roughness of the top surface of the data wiring fabricated according to the exemplary embodiment of the present invention is approximately 2 nm or less, and the root-mean-square roughness thereof is approximately 3 nm or less.

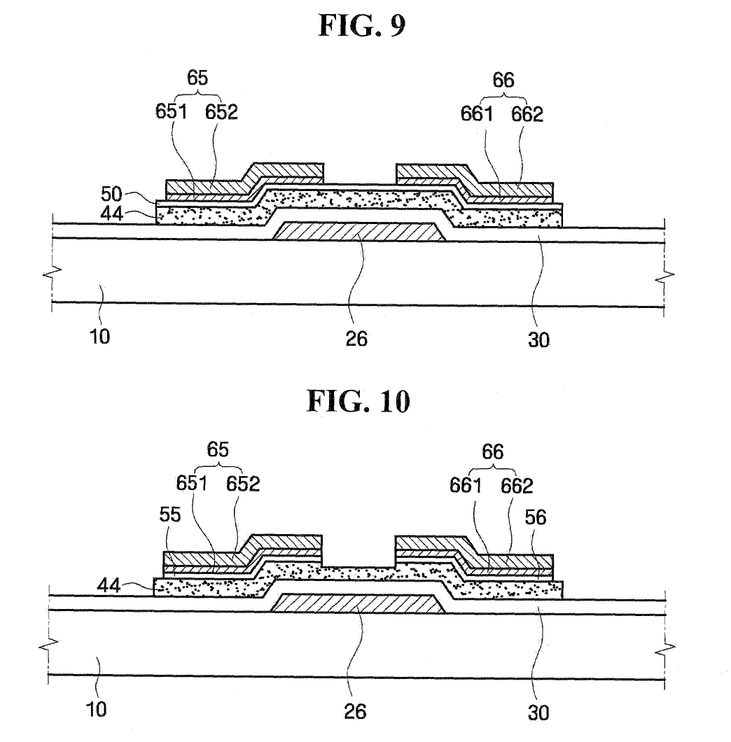

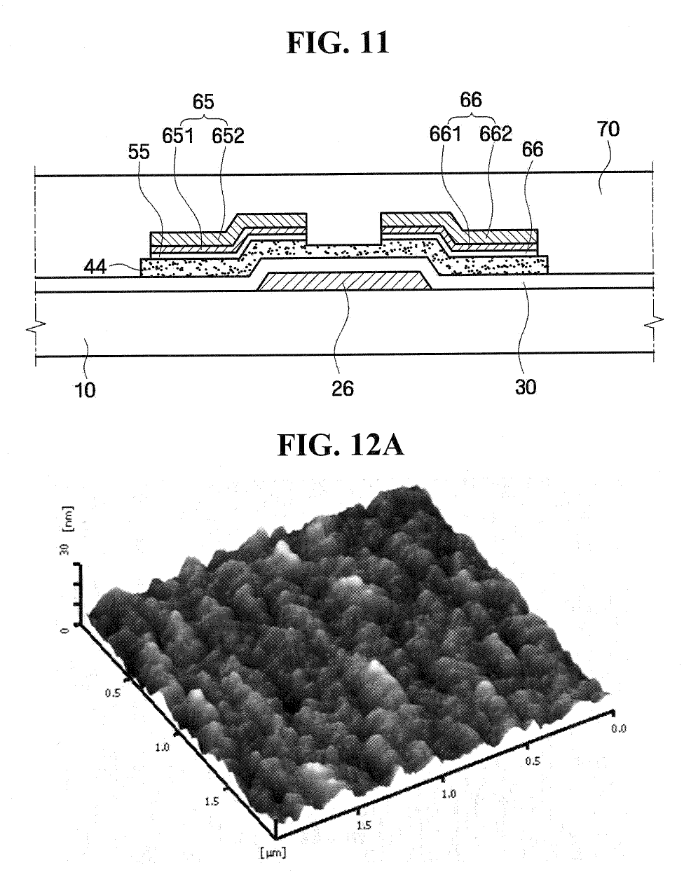

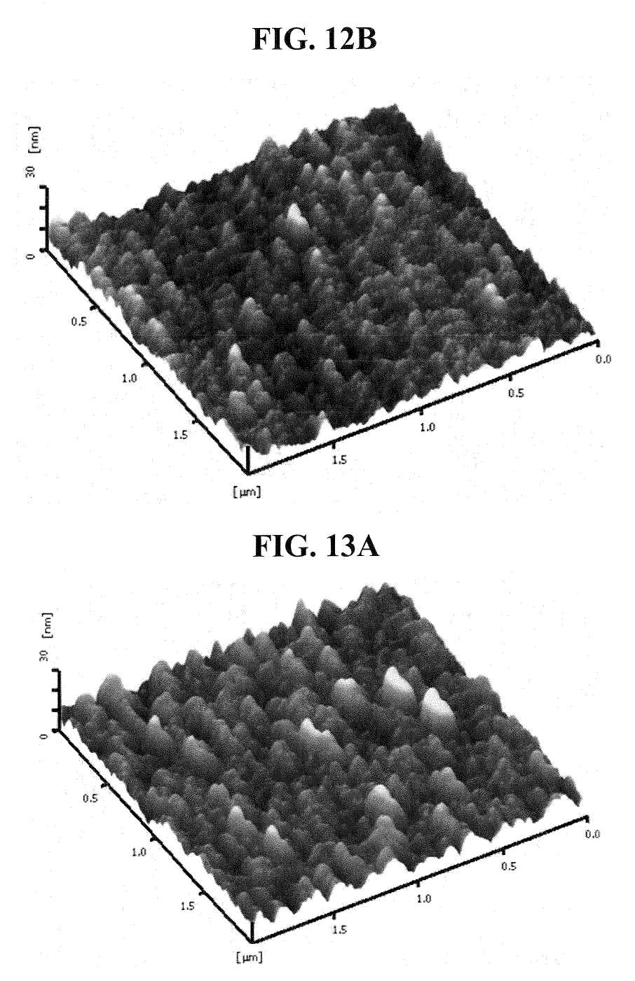

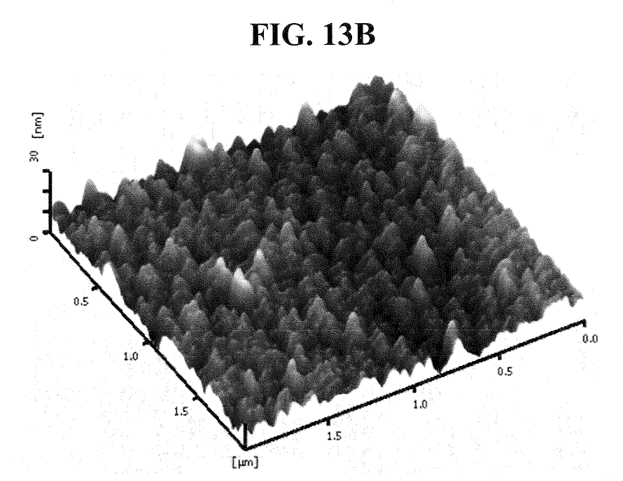

FIG. 12A, FIG. 12B, FIG. 13A, and FIG. 13B show images of the respective surfaces of the data wirings which were captured by an atomic force microscope (AFM). Specifically, FIG. 12A shows an AFM image of the top surface of the data wiring at a location where Experimental Example 1, Experimental Example 2, and Experimental Example 3 of Table 1 were conducted. FIG. 12B shows an AFM image of the top surface of the data wiring at a location where Experimental Example 4, Experimental Example 5, and Experimental Example 6 of Table 1 were conducted. FIG. 13A shows an AFM image of the top surface of the data wiring at a location where Comparative Experimental Example 1, Comparative Experimental Example 2, and Comparative Experimental Example 3 of Table 1 were conducted. FIG. 13B shows an AFM image of the top surface of the data wiring at a location where Comparative Experimental Example 4, Comparative Experimental Example 5, and Comparative Experimental Example 6 of Table 1 were conducted.

Referring to FIG. 12A, FIG. 12B, FIG. 13A, and FIG. 13B, the top surface of the data wiring fabricated according to the exemplary embodiment of the present invention (FIG. 12A and FIG. 12B) is more even, i.e. has a lower average roughness and a lower root-mean-square roughness, than that of the data wiring fabricated according to the comparative experimental examples (FIG. 13A and FIG. 13B).

The method of fabricating the TFT substrate according to the present invention may be applied not only to the above exemplary embodiment but also to an array-on-color filter (AOC) structure in which a color filter (not shown) is formed on the insulating substrate 10, and in which a TFT array is formed on the color filter.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of fabricating a thin-film transistor substrate, the method comprising:
forming a semiconductor layer and a conductive layer on an insulating substrate, the conductive layer comprising a lower layer and an upper layer;
forming a photosensitive film pattern on the conductive layer, the photosensitive film pattern comprising a first region and a second region, the second region being formed on both sides of the first region and being thicker than the first region;
etching the conductive layer and the semiconductor layer using the photosensitive film pattern as an etching mask;
removing the first region of the photosensitive film pattern;
etching a portion of the upper layer corresponding to a location of the removed first region;
removing the second region of the photosensitive film pattern; and
etching a portion of the lower layer corresponding to the location of the removed first region using the upper layer as an etching mask.

2. The method of claim 1, wherein the upper layer comprises an aluminum (Al) alloy, and
wherein the Al alloy of the upper layer comprises Al and one or more of nickel (Ni), copper (Cu), boron (B), cerium (Ce), lanthanum (La), or neodymium (Nd).

3. The method of claim 2, wherein the lower layer comprises molybdenum (Mo), Mo alloy, titanium (Ti), Ti alloy, chrome (Cr), Cr alloy, tantalum (Ta), or Ta alloy.

4. The method of claim 3, wherein etching the portion of the upper layer comprises a dry-etching process.

5. The method of claim 4, wherein a chlorine-based etching gas is used in the dry-etching process.

6. The method of claim 5, wherein the chlorine-based etching gas comprises Cl₂ or BCl₃.

7. The method of claim 6, wherein etching the portion of the lower layer comprises etching using an etching gas comprising a mixture of a fluorine-based gas and oxygen.

8. The method of claim 7, wherein the fluorine-based gas comprises SF₆, XeF₂, BrF₂, ClF₂, or a combination of the same.

9. The method of claim 1, wherein removing the second region of the photosensitive film pattern comprises oxygen plasma.

10. The method of claim 1, further comprising:
forming an ohmic contact layer, the ohmic contact layer being disposed between the semiconductor layer and the lower layer; and
etching the ohmic contact layer after etching the lower layer corresponding to the location of the removed first region.

11. The method of claim 10, wherein etching the portion of the lower layer comprises etching using a fluorine-based etching gas.

12. The method of claim 11, wherein the fluorine-based gas comprises SF₆, XeF₂, BrF₂, ClF₂, or a combination of the same.

13. The method of claim 1, further comprising performing plasma treatment using a fluorine-based gas after the etching of the lower layer.

14. A thin-film transistor substrate, comprising:
an insulating substrate;
gate wiring that extends on the insulating substrate in a first direction;
data wiring that extends on the gate wiring in a second direction, the data wiring comprising a lower layer and an upper layer; and
a semiconductor pattern disposed under the data wiring and having substantially the same shape as the data wiring except for a channel region,
wherein a root-mean-square roughness of a top surface of the data wiring is 3 nm or less.

15. The substrate of claim 14, wherein the upper layer comprises an Al alloy, and wherein the Al alloy of the upper layer comprises Al and one or more of Ni, Cu, B, Ce, La, Nd.

16. The substrate of claim 15, wherein the lower layer comprises Mo, Mo alloy, Ti, Ti alloy, Cr, Cr alloy, Ta, or Ta alloy.

17. The substrate of claim 16, wherein an average roughness of the data wiring is 2 nm or less.

18. The substrate of claim 17, wherein portions of the semiconductor pattern that protrude from respective sides of a source electrode and a drain electrode are 1 μm or less.

19. The substrate of claim 14, wherein an average roughness of the data wiring is 2 nm or less.

20. The substrate of claim 14, wherein portions of the semiconductor pattern that protrude from respective sides of the source electrode and the drain electrode are 1 μm or less.
